(19) United States
(12) Patent Application Publication
(10) Pub. No.: US 2023/0405711 A1
(43) Pub. Date: Dec. 21, 2023

(54) LASER OSCILLATOR AND LASER PROCESSING APPARATUS INCLUDING SAME

(71) Applicant: Panasonic Intellectual Property Management Co., Ltd., Osaka (JP)

(72) Inventor: YUTA KUROSAKI, Osaka (JP)

(21) Appl. No.: 18/456,483

(22) Filed: Aug. 26, 2023

Related U.S. Application Data
(63) Continuation of application No. PCT/JP2022/015785, filed on Mar. 30, 2022.

(30) Foreign Application Priority Data
Apr. 5, 2021 (JP) 2021-064008

(51) Int. Cl. B23K 26/0622; B23K 26/064

(52) U.S. Cl. CPC B23K 26/0622; B23K 26/064

(57) ABSTRACT

Provided is a laser oscillator including: anti-surge capacitor (44) that is connected in parallel with bypass switch (43) between first and second nodes (N1), (N2); first diode (45) that is connected in parallel with light emission circuit (42) and bypass switch (43) and in series with anti-surge capacitor (44) on a side close to first node (N1), and that rectifies a current to allow the current to flow in a direction from first node (N1) toward anti-surge capacitor (44); and current supply circuit (60) that supplies the current to light emission circuit (42) using electrostatic energy stored in anti-surge capacitor (44).

### TECHNICAL FIELD

The present disclosure relates to a laser oscillator including a light emission circuit having at least one laser diode and a bypass switch connected in parallel with the light emission circuit.

### BACKGROUND ART

PTL 1 discloses a laser oscillator including a light emission circuit having multiple laser diodes connected to each other in series, a current source that supplies a supply current to the light emission circuit, and a bypass switch connected in parallel with the light emission circuit. This laser oscillator includes a snubber circuit that is composed of a resistor and a capacitor connected to each other in series and that is connected in parallel with the bypass switch to suppress a surge voltage generated when the bypass switch is turned off.

### CITATION LIST

### Patent Literature PTL 1: Japanese Patent No. 6577575

### SUMMARY OF THE INVENTION

### Technical problem

Unfortunately, both of a current flowing from the current source into the capacitor when the bypass switch is switched from on to off and a current flowing out from the capacitor of the snubber circuit when the bypass switch is switched from off to on flow through the resistor of the snubber circuit in PTL 1. Thus, when switching frequency of the bypass switch is increased, a failure rate of the laser oscillator may increase due to heat generated by the resistor of the snubber circuit. Then, use of a large-sized resistance element that is less likely to generate heat as the resistor of the snubber circuit may cause the laser oscillator to be increased in size.

The present disclosure is made in view of such a point, and an object thereof is to increase a switching frequency of a bypass switch while suppressing an increase in size of a laser oscillator and an increase in a failure rate.

### Solution to Problem

To achieve the object above, the present disclosure provides a laser oscillator including: a light emission circuit that includes one laser diode or multiple laser diodes connected to each other in series and that has an anode of the laser diode or each of multiple laser diodes, the anode being connected between a first node and a second node while facing the first node; a current source that supplies a supply current between the first node and the second node using power output from an AC power source; a bypass switch connected between the first node and the second node in parallel with the light emission circuit; a capacitor connected between the first node and the second node in parallel with the bypass switch; a rectifier element that is connected in parallel with the light emission circuit and the bypass switch and connected in series with the capacitor on a side close to the first node to rectify a current to allow the current to flow in a direction from the first node toward the capacitor; and a current supply circuit that supplies a current to the light emission circuit using electrostatic energy stored in the capacitor.

As a result, when the bypass switch is switched from on to off, energy held by wiring inductance is transmitted to the capacitor through the rectifier element to charge the capacitor. Thus, surge voltage generated between the first and second nodes can be suppressed.

Additionally, while the capacitor is charged by the current flowing from the first node into the capacitor through the rectifier element, the capacitor can be discharged by causing the current supply circuit to supply a current to the light emission circuit. Thus, a resistor is not required to be provided, the resistor allowing both a current flowing into the capacitor and a current flowing out from the capacitor to flow through the resistor as in Cited document 1. Thus, switching frequency of the bypass switch can be increased while increase in size of the laser oscillator and increase in a failure rate are suppressed.

### Advantageous Effect of Invention

The present disclosure enables increasing the switching frequency of the bypass switch while suppressing the increase in size of the laser oscillator and the increase in a failure rate.

### BRIEF DESCRIPTION OF THE DRAWINGS

FIG. 1 is a schematic diagram illustrating a configuration of a laser processing apparatus including a laser oscillator according to a first exemplary embodiment of the present disclosure.

FIG. 2 is a circuit diagram of the laser oscillator according to the first exemplary embodiment of the present disclosure.

FIG. 3 is a diagram of a second exemplary embodiment, corresponding to FIG. 2.

FIG. 4 is a diagram of a third exemplary embodiment, corresponding to FIG. 2.

FIG. 5 is a diagram of a fourth exemplary embodiment, corresponding to FIG. 2.

FIG. 6 is a diagram of a fifth exemplary embodiment, corresponding to FIG. 2.

### DESCRIPTION OF EMBODIMENT

Hereinafter, exemplary embodiments of the present disclosure will be described in detail with reference to the drawings. The following description of preferable exemplary embodiments is merely illustrative in nature and is not intended to limit the present disclosure, and application or use of the present disclosure.

### First Exemplary Embodiment

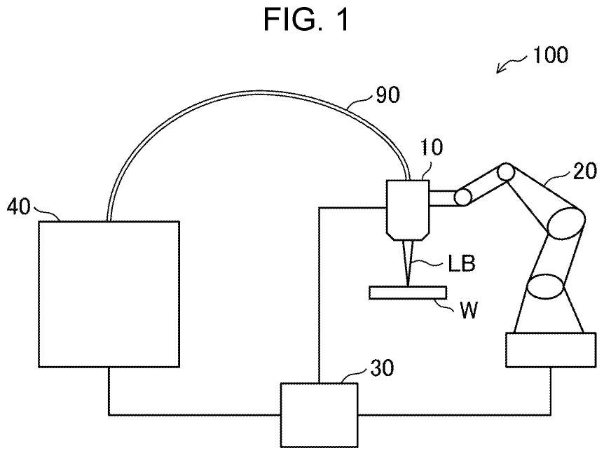

FIG. 1 illustrates a configuration of laser processing apparatus 100. Laser processing apparatus 100 is used to perform cutting, welding, and the like of workpiece W. Laser processing apparatus 100 includes laser processing head 10, manipulator 20, controller 30, laser oscillator 40 according to a first exemplary embodiment of the present disclosure, and optical fiber 90.

Laser processing head 10 irradiates workpiece W with laser beam LB from optical fiber 90. Manipulator 20 is provided at its leading end with laser processing head 10 attached, and moves laser processing head 10. Controller 30 controls operation of laser processing head 10, operation of manipulator 20, and laser oscillation of laser oscillator 40. Laser oscillator 40 emits laser beam LB to optical fiber 90 by oscillation. Optical fiber 90 allows laser beam LB emitted from laser oscillator 40 to pass through and guides laser beam LB to laser processing head 10. Laser processing head 10 emits laser beam LB having passed through optical fiber 90. The configuration described above allows laser processing apparatus 100 to irradiate workpiece W with laser beam LB emitted from laser oscillator 40 along a desired trajectory by operating laser processing head 10 and manipulator 20.

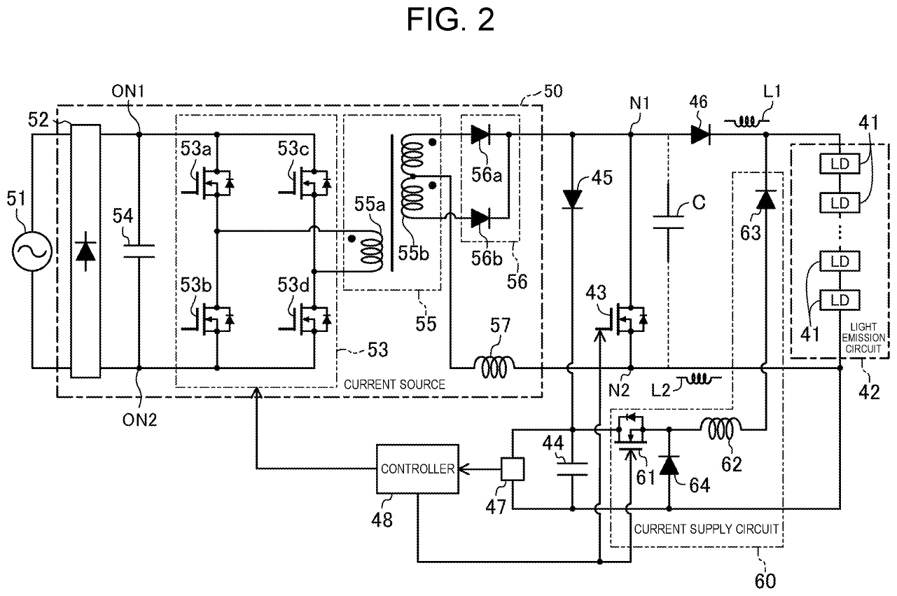

As illustrated in FIG. 2, laser oscillator 40 includes multiple laser diodes (LD) 41, current source 50, bypass switch 43 as a first switch, anti-surge capacitor 44, first and second diodes 45, 46, voltage measurement unit 47, current supply circuit 60, and controller 48.

Multiple laser diodes 41 are connected to each other in series between first and second nodes N1, N2 to constitute light emission circuit 42. Wiring between first and second nodes N1, N2. and laser diodes 41 has wiring inductances L1, L2. Multiple laser diodes 41 each have an anode facing a side close to first node N1.

Between first and second nodes N1, N2, parasitic capacitance C exists.

Current source 50 supplies a supply current between first and second nodes N1, N2 using power output from AC power source 51. Specifically, current source 50 includes current-source-side first rectifier circuit 52, current-source-side inverter circuit 53, current-source-side capacitor 54, current-source-side isolation transformer 55, current-source-side second rectifier circuit 56, and current-source-side reactor 57.

Current-source-side first rectifier circuit 52 converts power source voltage output from AC power source 51 into DC voltage and outputs the DC voltage from a pair of output nodes ON1, ON2. Current-source-side first rectifier circuit 52 includes a diode bridge, for example.

Current-source-side inverter circuit 53 generates first AC voltage for supply in accordance with voltage at each of output nodes ON1, ON2 of current-source-side first rectifier circuit 52. Specifically, current-source-side inverter circuit 53 includes first current-source-side upper arm switching element 53a and first current-source-side lower arm switching element 53b connected to each other in series between output nodes ON1, ON2, and second current-source-side upper arm switching element 53c and second current-source-side lower arm switching element 53d connected to each other in series between output nodes ON1, ON2. Each of switching elements 53a to 53d includes an N-channel MOS transistor (MOSFET: metal-oxide-semiconductor field-effect transistor).

Current-source-side capacitor 54 is connected between current-source-side first rectifier circuit 52 and current-source-side inverter circuit 53 in parallel with current-source-side first rectifier circuit 52 and current-source-side inverter circuit 53. Current-source-side capacitor 54 is connected between the pair of output nodes ON1, ON2 of current-source-side first rectifier circuit 52.

Current-source-side isolation transformer 55 converts the first AC voltage for supply output from current-source-side inverter circuit 53 into second AC voltage for supply. Current-source-side isolation transformer 55 includes current-source-side primary coil 55a and current-source-side secondary coil 55b. Voltage of current-source-side primary coil 55a serves as the first AC voltage for supply, and voltage of current-source-side secondary coil 55b serves as the second AC voltage for supply. Current-source-side primary coil 55a is connected between a node of first current-source-side upper arm switching element 53a and first current-source-side lower arm switching element 53b and a node of second current-source-side upper arm switching element 53c and second current-source-side lower arm switching element 53d.

Current-source-side second rectifier circuit 56 generates a DC supply current based on the second AC voltage for supply based on the first AC voltage for supply. Specifically, current-source-side second rectifier circuit 56 includes first and second rectification diodes 56a, 56b. First rectification diode 56a has an anode connected to one end of current-source-side secondary coil 55b, and second rectification diode 56b has an anode connected to the other end of current-source-side secondary coil 55b. First and second rectification diodes 56a, 56b each have a cathode connected to first node N1.

As described above, current-source-side inverter circuit 53 and current-source-side second rectifier circuit 56 are isolated from each other by current-source-side isolation transformer 55.

Current-source-side reactor 57 is connected between a middle part of current-source-side secondary coil 55b and second node N2.

Bypass switch 43 is connected between first and second nodes N1, N2 in parallel with light emission circuit 42. Bypass switch 43 includes an N-channel MOS transistor (MOSFET).

Anti-surge capacitor 44 is connected between first and second nodes N1, N2 in parallel with the bypass switch. Anti-surge capacitor 44 has one electrode connected to second node N2.

First diode 45 is a rectifier element that is connected in parallel with light emission circuit 42 and bypass switch 43 and connected to an electrode of anti-surge capacitor 44, the electrode being close to first node N1, in series with anti-surge capacitor 44, and that rectifies a current to allow the current to flow in a direction from first node N1 toward anti-surge capacitor 44.

Second diode 46 is a rectifier element that is connected between first node N1 and light emission circuit 42 and that rectifies a current in a direction from first node N1 toward light emission circuit 42.

Voltage measurement unit 47 measures voltage of anti-surge capacitor 44 as measurement voltage.

Current supply circuit 60 supplies a current to light emission circuit 42 using electrostatic energy stored in anti-surge capacitor 44. Current supply circuit 60 is composed of a so-called step-down converter. Specifically, current supply circuit 60 includes current-supply-circuit-side switch 61, current-supply-circuit-side reactor 62, current-supply-circuit-side first diode 63, and current-supply-circuit-side second diode 64.

Current-supply-circuit-side switch 61 is a semiconductor switch including an N-channel MOS transistor (MOSFET). Current-supply-circuit-side switch 61 has a drain connected to a node between anti-surge capacitor 44 and first diode 45.

Current-supply-circuit-side reactor 62 has one end connected to a source of current-supply-circuit-side switch 61.

Current-supply-circuit-side first diode 63 has an anode connected to the other end of current-supply-circuit-side reactor 62. Current-supply-circuit-side first diode 63 has a cathode connected to a node between second diode 46 and light emission circuit 42.

Current-supply-circuit-side second diode 64 has an anode connected to second node N2. Current-supply-circuit-side second diode 64 has a cathode connected to a node between current-supply-circuit-side switch 61 and current-supply-circuit-side reactor 62.

Current supply circuit 60 includes current-supply-circuit-side switch 61, current-supply-circuit-side reactor 62, and current-supply-circuit-side first diode 63 that are connected to each other in series. Current-supply-circuit-side switch 61, current-supply-circuit-side reactor 62, and current-supply-circuit-side first diode 63 form a closed circuit with anti-surge capacitor 44, the closed circuit being formed from one electrode of anti-surge capacitor 44 to the other electrode of anti-surge capacitor 44 through current-supply-circuit-side switch 61, current-supply-circuit-side reactor 62, and light emission circuit 42 in this order with current-supply-circuit-side switch 61 turned on.

Current supply circuit 60 configured as described above supplies a current from anti-surge capacitor 44 to light emission circuit 42 through current-supply-circuit-side reactor 62 with current-supply-circuit-side switch 61 turned on. When current-supply-circuit-side switch 61 is turned from on to off, current-supply-circuit-side second diode 64 conducts in a forward direction, and then energy held in current-supply-circuit-side reactor 62 is supplied to light emission circuit 42.

Controller 48 controls current-supply-circuit-side switch 61 of current supply circuit 60 so that target voltage is measured as measurement voltage by voltage measurement unit 47. The target voltage is set to be equal to or higher than the voltage of anti-surge capacitor 44 when each laser diode 41 included in light emission circuit 42 has forward voltage. When first and second diodes 45, 46 are equal in forward voltage, the target voltage is equal to or higher than the sum of forward voltages of laser diodes 41 included in light emission circuit 42. Controller 48 increases a duty ratio of a control signal input to a gate of current-supply-circuit-side switch 61 when measurement voltage measured by voltage measurement unit 47 exceeds the target voltage, and decreases the duty ratio of the control signal input to the gate of current-supply-circuit-side switch 61 when the measurement voltage measured by voltage measurement unit 47 is less than the target voltage. Here, the control signal is a periodic pulse signal, and the duty ratio of the control signal indicates a ratio of a period, during which current-supply-circuit-side switch 61 is turned on, to one cycle of the control signal.

Controller 48 also controls on and off of bypass switch 43.

Controller 48 further controls supply of a current using current source 50 by switching on and off of four switching elements 53a to 53d of current-source-side inverter circuit 53 of current source 50.

Next, laser oscillator 40 configured as described above first allows parasitic capacitance C between first and second nodes N1, N2 and anti-surge capacitor 44 to be charged by wiring inductances L1, L2 when bypass switch 43 is switched from on to off while controller 48 causes current source 50 to supply a current, and then voltage between first and second nodes N1, N2, or voltage applied to bypass switch 43 increases. As described above, when bypass switch 43 is switched from on to off, not only parasitic capacitance C but also anti-surge capacitor 44 is charged by wiring inductances L1, L2. Thus, surge voltage generated between first and second nodes N1, N2 can be suppressed more as compared with when no anti-surge capacitor 44 is provided. When the measurement voltage measured by voltage measurement unit 47 exceeds the target voltage, controller 48 increases the duty ratio of the control signal input to the gate of current-supply-circuit-side switch 61. This configuration allows current supply circuit 60 to supply a current to light emission circuit 42 so that the voltage of anti-surge capacitor 44, or the measurement voltage measured by voltage measurement unit 47 drops to the target voltage and is maintained at the target voltage. As a result, the voltage between first and second nodes N1, N2 is also maintained at a degree of predetermined voltage corresponding to the target voltage. Thus, setting the target voltage to an appropriate value enables preventing damage to a component between first and second nodes N1, N2 due to the surge voltage.

Additionally, the target voltage is set to be equal to or higher than the voltage of anti-surge capacitor 44 when the voltage of light emission circuit 42 is the sum of the forward voltages of laser diodes 41 included in light emission circuit 42, so that a pulse current flowing through light emission circuit 42 can rise faster and light emission circuit 42 can emit light faster than when the target voltage is set to be less than the voltage of anti-surge capacitor 44. Thus, narrowing a pulse width of the pulse current flowing through light emission circuit 42 or increasing frequency of the pulse current enables the amount of heat input to optical fiber 90 and laser processing head 10 to be finely adjusted, so that workpiece W can be processed more finely.

Thereafter, when controller 48 switches bypass switch 43 from off to on, zero voltage is applied to bypass switch 43. Then, a current flowing through light emission circuit 42 gradually decreases, and a current flowing through bypass switch 43 gradually increases.

Then, substantially zero current flows through light emission circuit 42, and this state is maintained for a predetermined time.

Repeatedly performing the above-described operation at regular time intervals enables the pulse current to flow through light emission circuit 42.

Thus, the first exemplary embodiment enables not only charging anti-surge capacitor 44 using a current flowing from first node N1 to anti-surge capacitor 44 through first diode 45, but also allowing anti-surge capacitor 44 to be discharged by causing current supply circuit 60 to supply a current to light emission circuit 42. Thus, a configuration as in Cited document 1 is not required, in which both the current flowing into the anti-surge capacitor and the current flowing out from the capacitor flow into the common resistor as in PTL 1. Thus, switching frequency of bypass switch 43 can be increased while increase in size of laser oscillator 40 and increase in a failure rate are suppressed.

Current-supply-circuit-side switch 61 is composed of a semiconductor switch, so that current-supply-circuit-side switch 61 can be switched between on and off at high speed. Thus, current supply circuit 60 can be increased in responsiveness.

### Second Exemplary Embodiment

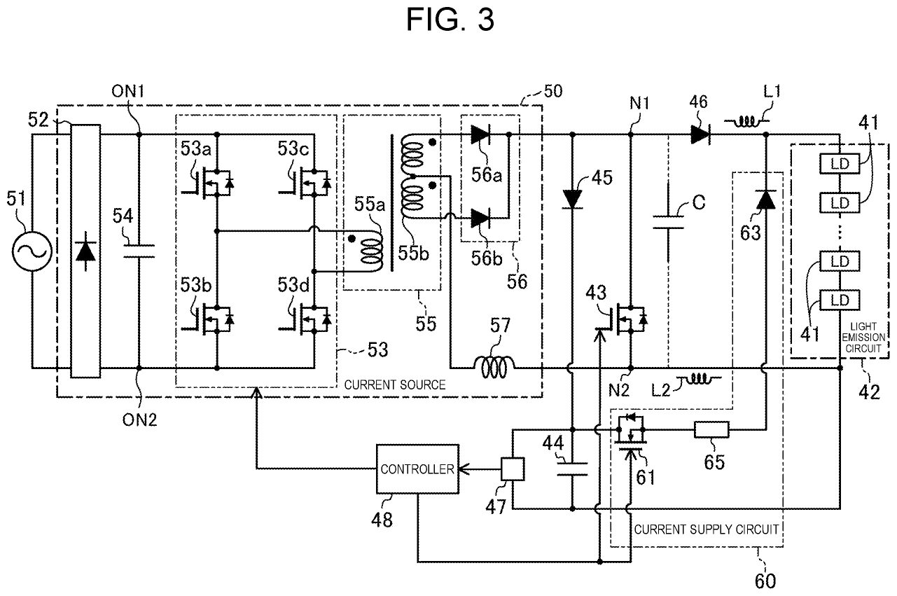

FIG. 3 illustrates laser oscillator 40 according to a second exemplary embodiment of the present disclosure. Current supply circuit 60 in the second exemplary embodiment is composed of a so-called linear regulator. Specifically, current supply circuit 60 includes resistor 65 for limiting a current value instead of current-supply-circuit-side reactor 62. Current supply circuit 60 does not include current-supply-circuit-side second diode 64.

Current supply circuit 60 supplies a current from anti-surge capacitor 44 to light emission circuit 42 through resistor 65 with current-supply-circuit-side switch 61 turned on, and does not supply a current to light emission circuit 42 with current-supply-circuit-side switch 61 turned off.

Other configurations and effects are identical to those of the first exemplary embodiment, so that the same configurations are denoted by the same reference numerals, and details thereof will not be described.

### Third Exemplary Embodiment

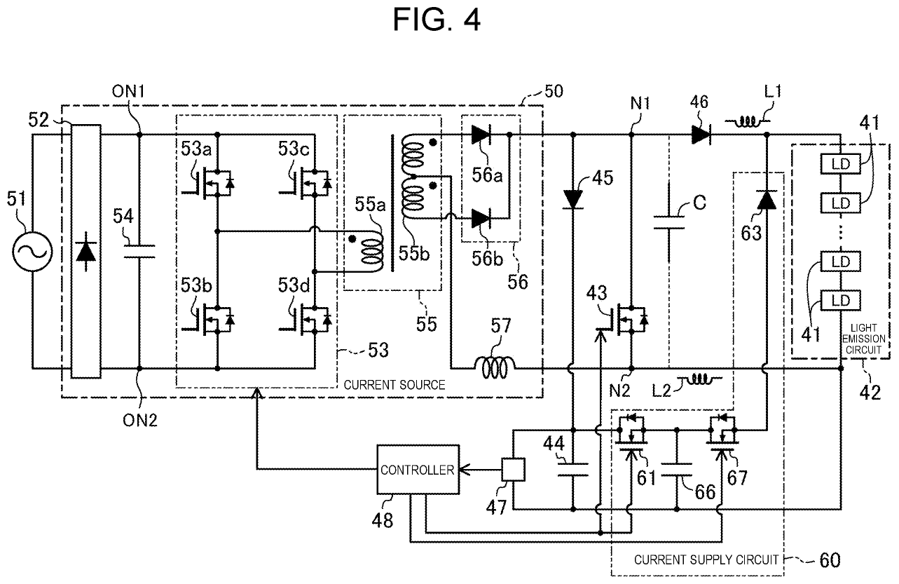

FIG. 4 illustrates laser oscillator 40 according to a third exemplary embodiment of the present disclosure. Current supply circuit 60 in the third exemplary embodiment is composed of a so-called switched capacitor circuit. Specifically, current supply circuit 60 includes light-emission-circuit-side capacitor 66 in place of current-supply-circuit-side second diode 64, and includes light-emission-circuit-side switch 67 in place of current-supply-circuit-side reactor 62.

Light-emission-circuit-side switch 67 is a semiconductor switch including an N-channel MOS transistor (MOSFET).

Controller 48 outputs a pulse signal having a polarity opposite to that of the control signal input to the gate of current-supply-circuit-side switch 61, the pulse signal serving as a control signal input to a gate of light-emission-circuit-side switch 67.

Thus, when current-supply-circuit-side switch 61 is turned on, light-emission-circuit-side switch 67 is turned off. Then, current supply circuit 60 charges light-emission-circuit-side capacitor 66 by causing a current to flow from anti-surge capacitor 44 to light-emission-circuit-side capacitor 66. In contrast, when current-supply-circuit-side switch 61 is turned off, light-emission-circuit-side switch 67 is turned on. Then, current supply circuit 60 supplies a current from light-emission-circuit-side capacitor 66 to light emission circuit 42.

Other configurations and effects are identical to those of the first exemplary embodiment, so that the same configurations are denoted by the same reference numerals, and details thereof will not be described.

### Fourth Exemplary Embodiment

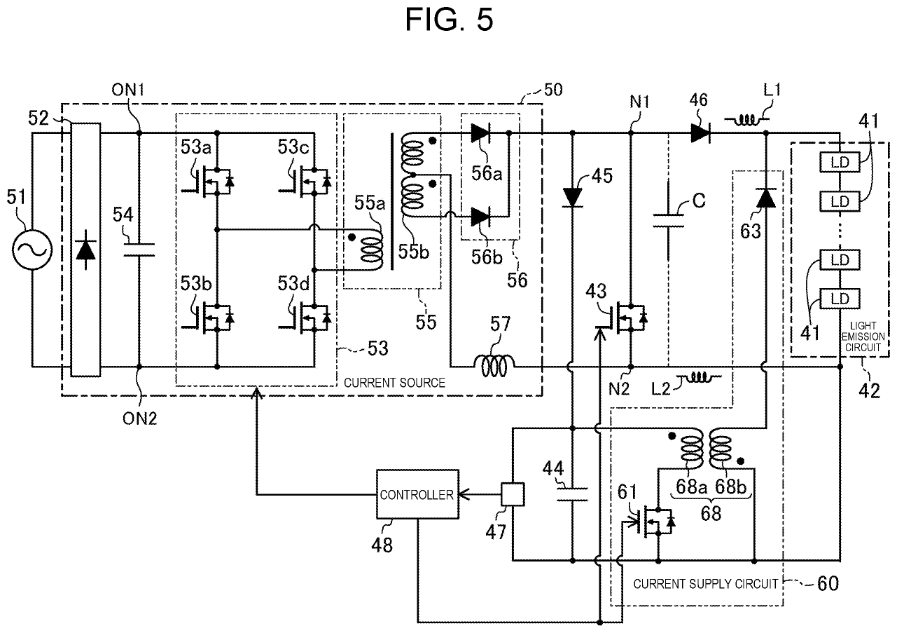

FIG. 5 illustrates laser oscillator 40 according to a fourth exemplary embodiment of the present disclosure. Current supply circuit 60 in the fourth exemplary embodiment is composed of a so-called flyback converter. Specifically, current supply circuit 60 includes current-supply-circuit-side isolation transformer 68, and does not include current-supply-circuit-side reactor 62 and current-supply-circuit-side second diode 64. Current-supply-circuit-side switch 61 has a source connected to second node N2.

Current-supply-circuit-side isolation transformer 68 includes current-supply-circuit-side primary coil 68a and current-supply-circuit-side secondary coil 68b.

Current-supply-circuit-side primary coil 68a has one end connected to a node between anti-surge capacitor 44 and first diode 45, and the other end connected to a drain of current-supply-circuit-side switch 61.

Current-supply-circuit-side secondary coil 68b has one end connected to the anode of current-supply-circuit-side first diode 63, and the other end connected to second node N2.

Thus, on-off control of current-supply-circuit-side switch 61 allows current-supply-circuit-side isolation transformer 68 to convert electrostatic energy stored in anti-surge capacitor 44 into output-side electric energy. Then, current supply circuit 60 supplies a current to light emission circuit 42 using the output-side electric energy.

Other configurations and effects are identical to those of the first exemplary embodiment, so that the same configurations are denoted by the same reference numerals, and details thereof will not be described.

### Fifth Exemplary Embodiment

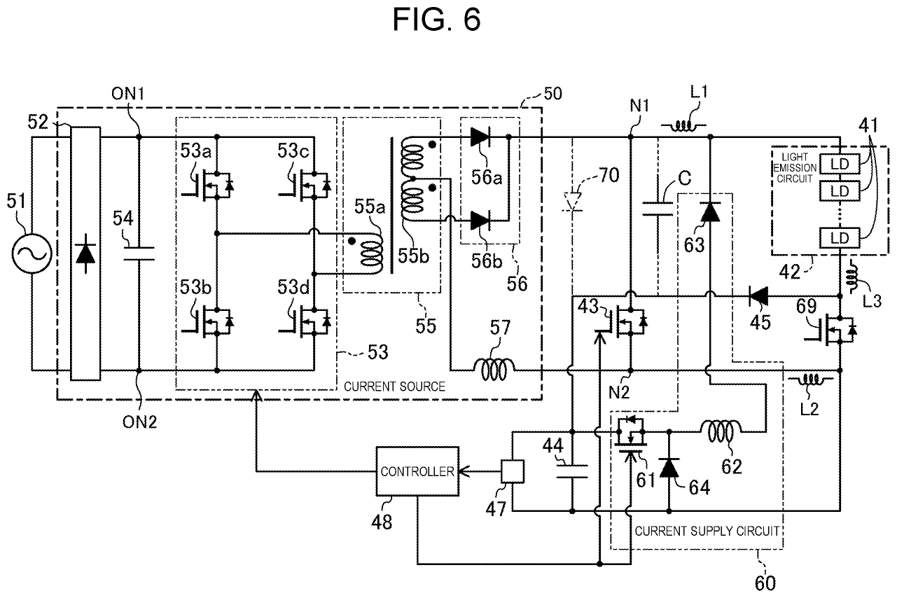

FIG. 6 illustrates laser oscillator 40 according to a fifth exemplary embodiment of the present disclosure. Laser oscillator 40 in the fifth exemplary embodiment further includes series switch 69 as a second switch. This series switch 69 is connected between first and second nodes N1, N2 in series with light emission circuit 42 and in parallel with bypass switch 43.

Then, first diode 45 of current supply circuit 60 has an anode connected to a node between light emission circuit 42 and series switch 69. Anti-surge capacitor 44 is connected in series with light emission circuit 42 and in parallel with series switch 69.

Thus, first diode 45 is connected in parallel with series switch 69 and in series with anti-surge capacitor 44 on a side close to first node N1 (close to light emission circuit 42), and rectifies a current to allow the current to flow from first node N1 toward anti-surge capacitor 44 through light emission circuit 42.

Controller 48 controls bypass switch 43 and series switch 69 so that the switches are turned on and off opposite to each other.

Laser oscillator 40 configured as described above first allows controller 48 to switch bypass switch 43 from on to off and switch series switch 69 from off to on while a current is supplied to current source 50, and then parasitic capacitance C between first and second nodes N1, N2 is charged by wiring inductances L1, L2 to increase voltage between first and second nodes N1, N2, or voltage applied to bypass switch 43.

Thereafter, while a current flowing through light emission circuit 42 increases and stabilizes after reaching a predetermined current value, the voltage applied to bypass switch 43 drops and stabilizes after reaching the sum of forward voltages of laser diodes 41 included in light emission circuit 42 and source-drain voltage of series switch 69 when the current having the predetermined current value flows through light emission circuit 42.

Thereafter, switching operation is performed in which bypass switch 43 is switched from off to on, and series switch 69 is switched from on to off. At this time, magnetic energy stored in wiring inductances L1, L2, and L3 causes a current to flow into anti-surge capacitor 44 through light emission circuit 42 and first diode 45. As a result, anti-surge capacitor 44 is charged to increase voltage of anti-surge capacitor 44. When the measurement voltage measured by voltage measurement unit 47 exceeds the target voltage, controller 48 increases the duty ratio of the control signal input to the gate of current-supply-circuit-side switch 61. This configuration enables series switch 69 to be prevented from being damaged due to overvoltage by lowering the voltage of anti-surge capacitor 44, or voltage generated across series switch 69. The fifth exemplary embodiment allows the target voltage to be set to be equal to or lower than voltage obtained by subtracting forward voltage of first diode 45 from withstand voltage of series switch 69.

In a state where such control is performed, the current flowing through light emission circuit 42 gradually decreases, and the current flowing through bypass switch 43 gradually increases. Additionally, the voltage across series switch 69 is maintained at a degree of voltage obtained by adding the forward voltage of first diode 45 to the target voltage.

Thereafter, the current flowing through light emission circuit 42 decreases to substantially zero, and then the amount of the current flowing through bypass switch 43 stabilizes. Then, this state is maintained for a predetermined time.

Repeatedly performing the above-described operation at regular time intervals enables the pulse current to flow through light emission circuit 42.

Thus, the fifth exemplary embodiment allows the target voltage to be set high within a range without damaging series switch 69 to increase the voltage across series switch 69 in the switching operation, thereby converting the magnetic energy stored in wiring inductances L1, L2, and L3 into electrostatic energy of anti-surge capacitor 44, so that the current flowing through light emission circuit 42 can fall faster. Thus, narrowing a pulse width of the pulse current flowing through light emission circuit 42 or increasing frequency of the pulse current enables the amount of heat input to optical fiber 90 and laser processing head 10 to be finely adjusted, so that workpiece W can be processed more finely.

Other configurations and effects are identical to those of the first exemplary embodiment, so that the same configurations are denoted by the same reference numerals, and details thereof will not be described.

The fifth exemplary embodiment described above may allow diode 70 indicated by a two-dot chain line in FIG. 6 to be connected in parallel with light emission circuit 42 and bypass switch 43, and to have an anode connected in series with anti-surge capacitor 44 on a side close to first node N1, the anode facing anti-surge capacitor 44 on the side close to first node Ni. This configuration enables suppressing surge voltage generated between first and second nodes N1, N2 as in the first exemplary embodiment.

Although light emission circuit 42 includes multiple laser diodes 41 connected in series in the first to fifth exemplary embodiments, light emission circuit 42 may include only one laser diode.

Although voltage of anti-surge capacitor 44 is measured by voltage measurement unit 47 as the measurement voltage in the first to fifth exemplary embodiments, voltage at another place may be measured as the measurement voltage as long as the voltage corresponds to the voltage of anti-surge capacitor 44. For example, surge peak voltage between first and second nodes N1, N2 may be measured as the measurement voltage in the first to fourth exemplary embodiments.

Although first diode 45 is provided as a rectifier element in the first to fifth exemplary embodiments, a MOSFET may be provided, the MOSFET rectifying a current to allow the current to flow in a direction from first node N1 toward anti-surge capacitor 44.

### INDUSTRIAL APPLICABILITY

As described above, the present disclosure enables acquiring a highly practical effect of increasing switching frequency of a bypass switch while suppressing an increase in size of a laser oscillator and an increase in failure rate, and thus is extremely useful and has high industrial applicability.

### REFERENCE MARKS IN THE DRAWINGS

100: laser processing apparatus

10: laser processing head

40: laser oscillator

41: laser diode

42: light emission circuit

43: bypass switch (first switch)

44: anti-surge capacitor

45: first diode (rectifier element)

47: voltage measurement unit

48: controller

50: current source

60: current supply circuit

61: current-supply-circuit-side switch (semiconductor switch)

68: current-supply-circuit-side isolation transformer

69: series switch (second switch)

90: optical fiber

LB: laser beam

N1: first node

N2: second node

1. A laser oscillator comprising:
a light emission circuit that includes one laser diode or a plurality of laser diodes connected to each other in series and that has an anode of the laser diode or each of the plurality of laser diodes, the anode being connected between a first node and a second node while facing the first node;
a current source that supplies a supply current between the first node and the second node using power output from an AC power source;
a bypass switch connected between the first node and the second node in parallel with the light emission circuit;
a capacitor connected between the first node and the second node in parallel with the bypass switch;
a rectifier element that is connected in parallel with the light emission circuit and the bypass switch and connected in series with the capacitor on a side close to the first node to rectify a current to allow the current to flow in a direction from the first node toward the capacitor; and
a current supply circuit that supplies a current to the light emission circuit using electrostatic energy stored in the capacitor.

2. The laser oscillator according to claim 1, further comprising:
a voltage measurement unit that measures measurement voltage corresponding to voltage of the capacitor; and
a controller that controls the current supply circuit to allow measurement voltage measured by the voltage measurement unit to be target voltage.

3. The laser oscillator according to claim 2, wherein the target voltage is set to be equal to or higher than voltage of the capacitor when voltage of the laser diode included in the light emission circuit becomes forward voltage.

4. The laser oscillator according to claim 1, wherein the current supply circuit includes a semiconductor switch, and constitutes a closed circuit with the capacitor and the semiconductor switch turned on, the closed circuit being formed from one electrode of the capacitor to another electrode of the capacitor through the semiconductor switch and the light emission circuit.

5. The laser oscillator according to claim 1, wherein the current supply circuit includes a transformer that converts electrostatic energy stored in the capacitor into output-side electric energy, and supplies a current to the light emission circuit using the output-side electric energy.

6. A laser oscillator comprising:
a light emission circuit that includes one laser diode or a plurality of laser diodes connected to each other in series and that has an anode of the laser diode or each of the plurality of laser diodes, the anode being connected between a first node and a second node while facing the first node;
a current source that supplies a supply current between the first node and the second node using power output from an AC power source;
a first switch connected in parallel with the light-emitting circuit;
a second switch connected between the first and second nodes in series with the light emission circuit and in parallel with the first switch;
a capacitor connected in series with the light emission circuit and in parallel with the second switch;
a rectifier element connected in parallel with the second switch and in series with the capacitor on a side close to the first node, the rectifier element rectifying a current to allow the current to flow in a direction from the first node toward the capacitor;
a current supply circuit that supplies a current to the light emission circuit based on electrostatic energy stored in the capacitor; and
a controller that performs switching operation of switching the first switch from off to on and switching the second switch from on to off.

7. A laser processing apparatus comprising:
the laser oscillator according to claim 1;
an optical fiber that allows a laser beam emitted from the laser oscillator to pass through; and
a laser processing head that emits the laser beam that has passed through the optical fiber.
